(19) United States
(12) Patent Application Publication
(10) Pub. No.: US 2012/0193219 A1
(43) Pub. Date: Aug. 2, 2012

(54) METHOD FOR DETERMINING PROCESS-SPECIFIC DATA OF A VACUUM DEPOSITION PROCESS

(75) Inventor: Volker LINSS, Dresden (DE)

(73) Assignee: VON ARDENNE ANLAGENTECHNIK GMBH, Dresden (DE)

(21) Appl. No.: 13/343,747

(22) Filed: Jan. 5, 2012

(30) Foreign Application Priority Data
Jan. 27, 2011 (DE) 10 2011 003 260.6
Feb. 22, 2011 (DE) 10 2011 004 513.9
Apr. 27, 2011 (DE) 10 2011 017 583.0

(51) Int. Cl. C23C 14/35

(52) U.S. Cl. 204/192.13

(57) ABSTRACT

A method for determining process-specific data of a vacuum deposition process, in which a substrate is coated in a vacuum chamber by a material detached from a target connected to a magnetron, an optical emission spectrum being recorded and process-significant data of the vacuum deposition process being determined therefrom for further processing in measurement or regulating processes, is optimized to minimize errors in the determination of process-significant data. At least three intensities of spectral lines of at least two process materials are determined from the optical emission spectrum. From these, single and multiple intensities are mathematically correlated with and to one another and a process-significant datum, which is used in subsequent measurement or regulating processes, is determined from the relation results by a further mathematical relation.

### CROSS REFERENCE TO RELATED APPLICATIONS

This application claims priority of German applications 10 2011 003 260.6 filed on Jan. 27, 2011, 10 2011 004 513.9 filed on Feb. 22, 2011, and 10 2011 017 583.0 filed on Apr. 27, 2011, all of which are hereby incorporated by reference herein in their entirety.

### BACKGROUND ART

The invention relates to a method for determining process-specific data of a vacuum deposition process, in which a substrate is coated in a process space in a vacuum chamber by means of a material detached from a target connected to a magnetron while applying a target voltage provided by a regulated voltage source between the target and a back electrode and while introducing a process gas into the vacuum chamber, an optical emission spectrum being recorded and process-significant data of the vacuum deposition process being determined therefrom for further processing in measurement or regulating processes.

In what follows, intensity is intended to mean the value of the intensity of a spectral line of a material. When reference is made to a plurality of intensities of a material, this means that a plurality of spectral lines are defined from a spectrogram, in their height i.e. the value of the intensity of the respective spectral line is determined and processed further as an intensity.

A process gas as referred to below is used inter alia to set the pressure in the vacuum space. It may consist of a working gas which is inert i.e. does not chemically influence the process, for example argon, krypton or xenon. For reactive processes, however, the process gas may also consist of a reactive gas, for example oxygen, in order to initiate chemical reactions during the layer deposition, for example oxygen for oxidation. The process gas may also consist of a mixture of working gas and reactive gas.

The process gas, in particular the working gas and the reactive gas, are materials involved in the coating process, also referred to as process materials for brevity in the context of the invention.

Another process material is the target material of which a target of a magnetron consists, for example aluminium or zinc.

In order to ensure the deposition of a layer with consistent parameters, it is necessary to keep the working point of the coating process constant over a long time during which the target material is consumed. In particular, homogeneity is to be maintained in a long-term stable manner with respect to the layer thickness, the layer composition (doping) and further properties, such as sheet resistance. The progressive consumption of the target material makes this difficult. Primarily, the positional relationships between the target surface, magnetic field and gas inflow change geometrically as a result of the consumption.

By means of first calibration (so-called trimming), gas pressure distributions of working and reactive gases (for these terms, see below) can be carried out.

The pressures of the gases and the target voltage, which are also referred to as process parameters, are readjusted in the course of the process. The rotational speed in the case of a rotating magnetron is also another process parameter.

Because of the substrate passing through, it is also necessary to automatically readjust the process parameters rapidly. One solution, in which the ratio of two intensities is used for the regulation, has already been described in DE 10 2009 053 903 B2.

The checking of longterm stability is based on optical emission spectroscopy (OES) by means of two lines from the plasma which is formed over the target surface when the target voltage is applied in a vacuum. In this case, intensity lines at discrete wavelengths provide information about states of materials involved in the coating process, i.e. process materials as mentioned above.

The plasma is observed, and process parameters are readjusted in order to ensure constant layer parameters, in particular a constant sheet resistance of the growing layer.

Conventional (economical) spectrometers and their arrangement in the vicinity of the process present disadvantages with respect to the measured intensities or their absolute values (accuracy, deposits, variations). The sometimes unsharp resolution as a function of wavelength means that compromises have to be made in relation to readily identifiable (usable in control technology) intensity lines. In some cases, the lines are also very close together.

DE 103 41 513 B4 “Method for regulating the reactive gas flow in reactive plasma-enhanced vacuum coating processes” has already described observation of two lines of the OES signal and a solution for regulating the reactive gas flow in reactive plasma-enhanced vacuum coating processes, in which a controlled variable, which is determined by a plasma of the vacuum coating process, is recorded from the vacuum chamber as a controlled system by means of optical spectroscopy in a measuring element and the amount of a reactive gas supplied to the vacuum coating process is adjusted as a manipulated variable. The controlled variable is in this case employed as a value calculated from a measurement value of the intensity of a spectral line of the coating material involved in the process and a measurement value of the intensity of a spectral line of the reactive gas, or as a value calculated from a value to be determined of the corresponding intensities. In the arrangement likewise disclosed therein, the measuring element contains an acousto-optical spectrometer comprising a control input which is connected to a regulator output.

Although the intensities of two lines were correlated with one another and used as a controlled variable in this known solution, the reactive gas flow was however used as a manipulated variable, which does not sufficiently ensure consistency of the layer parameters, for example a constant sheet resistance, of the growing layer with progressive target erosion.

EP 1 553 206 A1 describes a magnetron sputtering method comprising working point regulation. In this case, the ratio of two intensities of spectral lines of materials involved in the coating process is used as a controlled variable for the regulation. In this regulation, the target voltage serves as a manipulated variable. With the invention, it has been found that the effect of such working point regulation can be improved.

### BRIEF SUMMARY OF THE INVENTION

It is now an object of the invention to minimize errors in the determination of process-significant data, which are caused by the measurement position and/or by the spectrometer, in order to render subsequent measurement or regulating processes more reliable.

According to the invention, the object is achieved in that at least three intensities I₁ . . . I₃ of spectral lines of at least two process materials are determined from the optical emission spectrum. A first relative intensity R₁ is calculated from one pair of the intensities I₁ . . . I₃ by a first mathematical relation. A second relative intensity R₂ is calculated from another pair of the intensities I₁ . . . I₃ by a second mathematical relation. Finally, an intensity relation IV is calculated as a process-significant datum from the first relative intensity R₁ and the second relative intensity R₂ by a third mathematical relation. This process-significant datum is then used in subsequent measurement or regulating processes, so that their accuracy and reliability are increased.

In one configuration of the method, at least four intensities I₁ . . . I₄ of at least two process materials are determined. The first relative intensity R₁ is calculated respectively from two of the intensities I₁ . . . I₄ which do not derive from the same process material. The second relative intensity R₂ is calculated respectively from two others of the intensities I₁ . . . I₄ which do not derive from the same process material.

In this way, it is possible to calibrate the intensities of one material with respect to another material.

By the inventive use of a plurality of lines for the process control and for ascertaining the properties of the growing layer, account is taken of the fact that the line intensities naturally depend on the excitation conditions. For example, the ratio of a Zn line to an O line varies as a function of the pressure because the interaction cross sections depend differently on the electron temperature (i.e. on the pressure).

A fundamental advantage of the invention, irrespective of its use, is that by virtue of the mathematical relations, it no longer uses the absolute values of the intensities which are susceptible to error, or simple relative intensities whose error still remains high, but instead a third relative intensity obtained from two relative intensities whose error is then largely freed of perturbing variables. The nature of the mathematical relations, the choice of the intensities and the materials from which these intensities are obtained, are also determined by the use of the process-significant data, as will be explained in more detail below.

One use of the invention relates to a method for regulating vacuum deposition processes in which spectra of materials that are involved in the process are recorded in situ, a plurality of intensities of process materials are determined therefrom and are mathematically correlated with one another, and the result of the mathematical relation is used as a controlled variable of a control loop which sets a process parameter as a manipulated variable so that the result of the mathematical relation tracks a reference variable.

In order to ensure a high layer quality, it is necessary to avoid variation of layer parameters due to increasing target erosion during the coating process by ensuring longterm stabilization of the working point.

The invention may then be aimed in particular at longterm stabilization of the layer quality in deposition processes, and in this context particularly at the development of a long-term stable reactive process for depositing Zn:O as TCO. In this case, a substrate is coated in a process space by means of a material detached from a target connected to the magnetron while applying a target voltage provided by a regulated voltage source between the target and a back electrode and while introducing a process gas into the vacuum chamber, the power or the discharge current being regulated by means of an oxygen flow.

For such a use of the invention:
at least four intensities I₁ . . . I₄ of at least two process materials are determined, the intensity I₁ of a first spectral line of a process material and the intensity I₂ of a second spectral line of a process material being measured at a first position in the process space and the first relative intensity R₁ being formed therefrom by the first mathematical relation f₁(I₁,I₂),
an intensity I₃ of the first spectral line and an intensity I₄ of the second spectral line are measured at the second position in the process space different from the first position, and the second relative intensity R₂ is formed therefrom by the second mathematical relation f₂(I₃,I₄),
and the third mathematical relation f₃ is formed from the first relative intensity R₁ and the second relative intensity R₂ by f₃={f₁(I₁,I₂), f₂(I₃,I₄)}, the result of which is used as an intensity relation IV as a controlled variable in the regulating process.

This regulation may be carried out by tracking the target voltage U_{T} and/or the speed of a relative movement between the magnet system and the target as a manipulated variable of the regulation so that the intensity relation IV as a controlled variable of the regulation is kept constant at a setpoint value IV_{S} of the intensity relation IV which is set as a reference variable.

Control of the target voltage and/or the speed of the relevant movement can be carried out with relatively little outlay. Speed regulation or voltage regulation are provided in any case, in order to keep the values constant in the course of operation. These regulations may then be used to set the voltage and/or speed so that the intensity relation is kept at a constant value.

In one configuration of the method, the second mathematical relation is of the same type as the first mathematical relation (f₁=f₂).

Preferably, a spectral line of the target material may be selected as the first spectral line and a spectral line of a reactive gas may be selected as the second spectral line.

It is desirable to use spectral lines which are significant as possible, in order to increase the accuracy of the method according to the invention. To this end, the spectral lines of different materials have been indicated above. The significance can furthermore be increased by selecting at least one of the spectral lines as an emission line which is attributable not to the neutral material state but to the excited material state (for example an ionized zinc line).

The basis of the method according to the invention is that a unique association of layer properties, voltage value of the target voltage, speed of the relative target movement and the intensity of spectral lines can be established. In this case, it is furthermore to be noted that perturbing influences on this unique association can be excluded by forming an intensity relation of two intensities.

The intensities may preferably be obtained by implementing the first and second mathematical relations in the form of ratio formation: f₁=I₁/I₂ and f₂=I₃/I₄.

The third mathematical relation may be implemented in the form of ratio formation f₃=f₁(I₁,I₂)/f₂(I₃,I₄) or averaging f₃=(f₁(I₁,I₂)+f₂(I₃,I₄))/2.

The aforementioned association may then expediently be used to define the setpoint value, by establishing the intensity relation IV for a value aᵢ of a layer property a to be achieved from a function IV=f(a).

To this end, the function IV=f(a) may be recorded during a calibration coating process by measuring values aᵢ of the layer property and, if a current value aₙ does not match the values aᵢ, modifying the target voltage and/or the speed of the relative movement between the magnet system and the target until a subsequent value aₙ₊ₓ corresponds to the value of the intended layer property, and using the intensity relation IV thereby to be determined as a setpoint value IV_{S} and setting it as a reference variable.

It is also possible to configure the method in such a way that a calibration coating process as presented above, which leads to highly reproducible results and therefore increases the accuracy of the method but is wide-ranging, can be reduced in terms of its outlay. It is therefore proposed that the setpoint value IV_{S} be determined for a value aᵢ of a layer property a to be achieved by measuring values aᵢ of the layer properties during a coating process and, if a current value aₙ does not match the values aᵢ, modifying the target voltage and/or the speed of the relative movement between the magnet system and the target until a subsequent value aₙ₊ₓ corresponds to the value of the intended layer property, and using the intensity relation IV thereby to be determined as a setpoint value IVₛ and setting it as a reference variable. It is therefore possible to generate not a set of characteristic curves from which various parameters can be read, but instead merely to determine the one setpoint value relevant to the value of the layer parameter.

The first alternative of the solution, namely varying the target voltage U_{T}, may be used for sputtering processes in devices with a static arrangement between the target and the magnet system as well as with a dynamic arrangement, and the second alternative for dynamic arrangements in which, however, both alternatives may be employed.

If the invention is used in the case of a planar magnetron, a relative movement may be carried out by moving the plasma generated over the target relative to the target surface. This may, for example, be achieved by a mobile magnet system below the target. However, the planar magnetron itself may also be moved relative to the substrate. In a particular configuration of the method according to the invention, the speed of these two relative movements may be controlled so as to keep the intensity relation constant.

The invention is also, and in particular, suitable for use in the case of a tubular magnetron. The tubular magnetron has an elongate magnet system preferably lying transversely to the transport direction of the substrate, around which a tubular target is rotatably arranged. Therefore, inter alia, more uniform target erosion is achieved and the target material yield is increased. In the present invention, the rotational movement may be considered as a relative movement of the tubular target relative to the substrate, the rotational speed of which can be controlled.

In practice, it has been found that the intensities of spectral lines vary during a target revolution. In order to exclude the influence of such a variation on the method according to the invention, it is preferable for the intensity relation to be generated as an average value over at least one revolution of the tubular magnetron.

The method presented above is preferably suitable for a single magnetron inside a vacuum chamber. Two magnetrons may influence one another via the plasma and different burning voltages. For this reason according to a preferred embodiment, in the case of two magnetrons arranged in a vacuum chamber, the regulation is respectively carried out separately for each magnetron. The separation of the two regulations can be reinforced, and the mutual influence minimized, by using at least one intensity of a different spectral line from the other respective magnetron for each magnetron. Thus, different intensity relations are used in the two regulations.

In another configuration, which is useful for the regulation, four intensities I₁ . . . I₄ are determined from three process materials. The first intensity I₁ is determined from a first process material, the second intensity I₂ is determined from a second process material, and the third intensity I₃ and the fourth intensity I₄ are determined from a third process material. The first intensity I₁ is correlated with the third intensity I₃ by means of the first mathematical relation to form the first relative intensity R₁, the second intensity I₂ and the fourth intensity I₄ are correlated by means of a second mathematical relation to form the second relative intensity R₂. The intensity relation IV is determined from the first relative intensity R₁ and the second relative intensity R₂ by means of a third mathematical relation and used as a controlled variable in the control loop.

Here, it is expedient for the target voltage process parameter to be used as a manipulated variable in the control loop.

In the case of reactive deposition processes, the reactive gas flow process parameter may be used as a manipulated variable.

Furthermore, in the case of reactive deposition processes, it is possible for the first to fourth intensities I₁-I₄ to be determined from the process materials: working gas, reactive gas and target material.

An attempt may thus be made, for example, to “calibrate” the intensities of lines of the layer elements with the respect to intensities of the lines of the working gas.

This could, for example, be of the form:

[I(Zn)/I(Ar,1)]/[I(O)/I(Ar,2)]

where
I(Zn) is the intensity of a zinc line,
I(O) is that of an oxygen line,
I(Ar,1) is the intensity of a first argon line and
I(Ar,2) is the intensity of a second argon line.

The most expedient relation may also have a different mathematical form, since the pure ratio is a good approximation only in a particular range.

According to another possible use of the method according to the invention, namely measuring the doping, in the case of coating with two target materials, three intensities I₁ . . . I₃ are determined from three process materials. The first intensity I₁ is determined from a first target material, the second intensity I₂ is determined from a second target material and the third intensity I₃ is determined from a third target material. The first intensity I₁ is correlated with the second intensity I₂ by means of the first mathematical relation to form the first relative intensity R₁, the second intensity I₂ and the third intensity I₃ are correlated by means of a second mathematical relation to form the second relative intensity R₂. The intensity relation IV is determined from the first relative intensity R₁ and the second relative intensity R₂ by means of a third mathematical relation and transmitted as a process-significant datum of a measurement for doping of the deposited layer with one or other target material.

This method may be used particularly in the case of an aluminium zinc oxide (AZO) coating. In this case, the first relative intensity R₁ is determined from an intensity of the target material aluminium and from an intensity of the target material zinc, and the second relative intensity R₂ is determined from an intensity of the reactive gas oxygen and the intensity of the target material aluminium or the intensity of the target material zinc.

One possibility consists in determining the first relative intensity by R₁=I₁/I₂, the second relative intensity by R₂=I₃/I₁, and the third intensity relation by IV=R₁/R₂.

In this way, it is possible to obtain somewhat more information about the doping concentration. At least 3 lines would then be needed a priori in the case of AZO: zinc, oxygen and aluminium (relation for example [I(Zn)/I(Al)]/I(O)/I(Zn)]; optionally also with different Zn lines).

### BRIEF DESCRIPTION OF THE DRAWING FIGURES

The invention will be described in more detail below with the aid of four exemplary embodiments. In the appended drawings:

FIG. 1 shows the method according to the invention in a first exemplary embodiment, illustrated with reference to a control loop having the target voltage as a manipulated variable and

FIG. 2 shows the method according to the invention in a second exemplary embodiment, illustrated with reference to a control loop having the rotational speed as a manipulated variable,

FIG. 3 shows the position of the spectral lines and their intensities for the working gas (AG) reactive gas (RG) and target materials (TM) in the spectrogram,

FIG. 4 shows the time profile of the absolute values of the intensities of the process materials: working gas (AG) reactive gas (RG) and target material (TM),

FIG. 5 shows the representation of the determination of the intensity relation IV from the four intensities of the three process materials: working gas (AG) reactive gas (RG) and target material (TM),

FIG. 6 shows the time profile of the absolute values of the intensities of the three process materials: first target material (TMa), second target material (TMb) and reactive gas (RG) and

FIG. 7 shows the representation of the determination of the intensity relation IV from the four intensities of the three process materials: first target material (TMa), second target material (TMb) and reactive gas (RG).

### DETAILED DESCRIPTION

In the following exemplary embodiments, it will be assumed that a substrate transported in the longitudinal direction in a vacuum coating apparatus is coated using a tubular magnetron arranged transversely to the transport direction. A layer which has various layer properties is in this case deposited. In parallel with the regulations according to the invention as presented here, a regulation known per se regulates the oxygen flow by means of the power. This regulation is not represented in detail in the figures.

In this exemplary embodiment, which relates to a reactive process for the deposition of ZnO:Al, the resistivity p is considered—as generic example for all other possible layer properties a—which is intended to have a particular value and should in particular be constant and homogeneous over the length of the substrate.

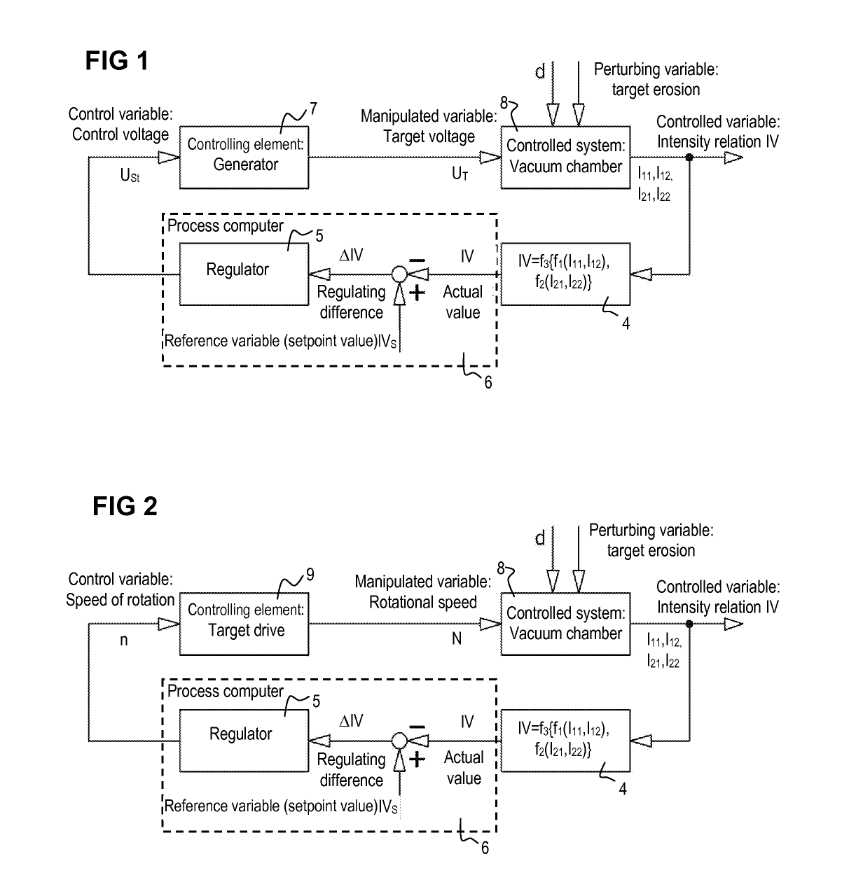

As shown in FIG. 1, the intensities I₁₁, I₂₁, I₁₂ and I₂₂ of the first and second spectral lines are respectively measured at the first and second positions in the process space by means of one or more optical emission spectrometers as measuring elements 4. A first mathematical relation f₁(I₁₁,I₂₁) and a second mathematical relation f₂(I₁₂,I₂₂) are then formed therefrom. In this case, the second mathematical relation is of the same type as the first mathematical relation (f₁=f₂) this means that the second mathematical relation is likewise produced by ratio formation when the first mathematical relation is carried out as ratio formation.

By means of a third mathematical relation f₃, an intensity relation IV is formed from the first and second mathematical relations f₃={f₁(I₁₁, I₂₁), f₂(I₁₂,I₂₂)}. Their result is used as a controlled variable of the regulation.

From a prior calibration coating process, the value pairs {IVᵢ,ρᵢ} are now available for a value aᵢ of an i^{th} measurement of a layer property a, for example with ρᵢ as the resistivity thereby determined.

If a particular resistivity p is now intended to be set, then the corresponding IV value is taken from the corresponding value pair and used as a setpoint value IV_{S}. The control deviation ΔIV is then calculated from the actual value IV and the setpoint value IV_{S}, and delivered to a regulator 5. The regulator 5 and the calculation represented here are implemented in a process computer 6. The latter also determines the corresponding value of a control voltage Uₛₜ which is delivered to the voltage-regulated generator 7 as a controlling element, from which a target voltage U_{T} is set in the latter as an output voltage which is applied to the target in the vacuum chamber 8, which can be considered as a controlled system.

Another possibility for keeping the intensity relation IV constant is to vary the target rotational speed N, the target voltage being kept constant by means of the oxygen flow.

As shown in FIG. 2, intensities I₁₁, I₂₁, I₁₂ and I₂₂ of the first and second spectral lines are again measured respectively at the first and second positions in the process space by means of one or more optical emission spectrometers as measuring elements 4. A first mathematical relation f₁(I₁₁,I₂₁) and a second mathematical relation f₂(I₁₂,I₂₂) are then formed therefrom. In this case, the second mathematical relation is likewise of the same type as the first mathematical relation (f₁=f₂). This means that the second mathematical relation is likewise produced by ratio formation when the first mathematical relation is carried out as ratio formation.

By means of a third mathematical relation f₃, an intensity relation IV is formed from the first and second mathematical relations f₃={f₁(I₁₁,I₂₁), f₂(I₁₂,I₂₂)}. Their result is used as a controlled variable of the regulation.

From a prior calibration coating process, the value pairs {IVᵢ,ρᵢ} are now available for a value aᵢ of an i^{th} measurement of a layer property a, for example with ρᵢ as the resistivity thereby determined.

If a particular resistivity p is now intended to be set, then the corresponding IV value is taken from the corresponding value pair and used as a setpoint value IV_{S}. The control deviation ΔIV is then calculated from the actual value IV and the setpoint value IV_{S}, and delivered to a regulator 5. The regulator 5 and the calculation represented here are likewise implemented in a process computer 6. The latter also determines the corresponding value of a speed of rotation n which is delivered to the voltage-regulated generator 7 as a controlling element, from which the latter sets a target rotational speed N that determines the relative speed between the target and the substrate in the vacuum chamber 8, which can be considered as a controlled system.

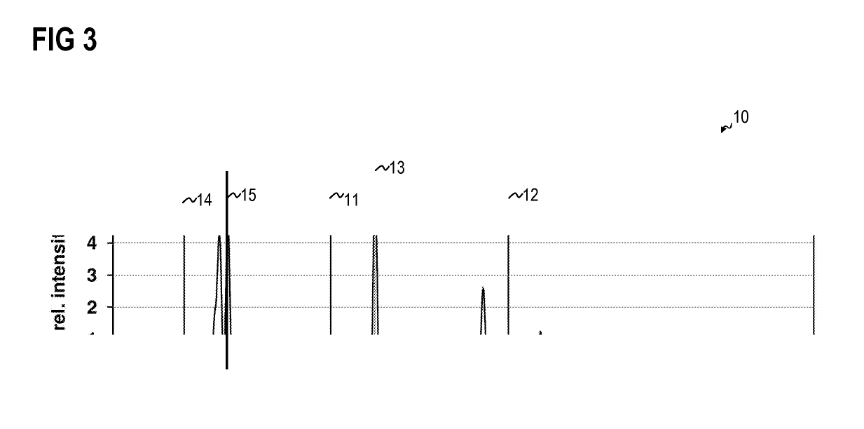

In a spectrogram 10, FIG. 3 represents a first spectral line 11 of the working gas, in this case argon (Ar), a second spectral line 12 of the working gas, a spectral line 13 of the reactive gas, in this case oxygen (O₂), a spectral line 14 of a first target material, in this case aluminium (Al), and a spectral line 15 of a second target material, in this case zinc (Zn).

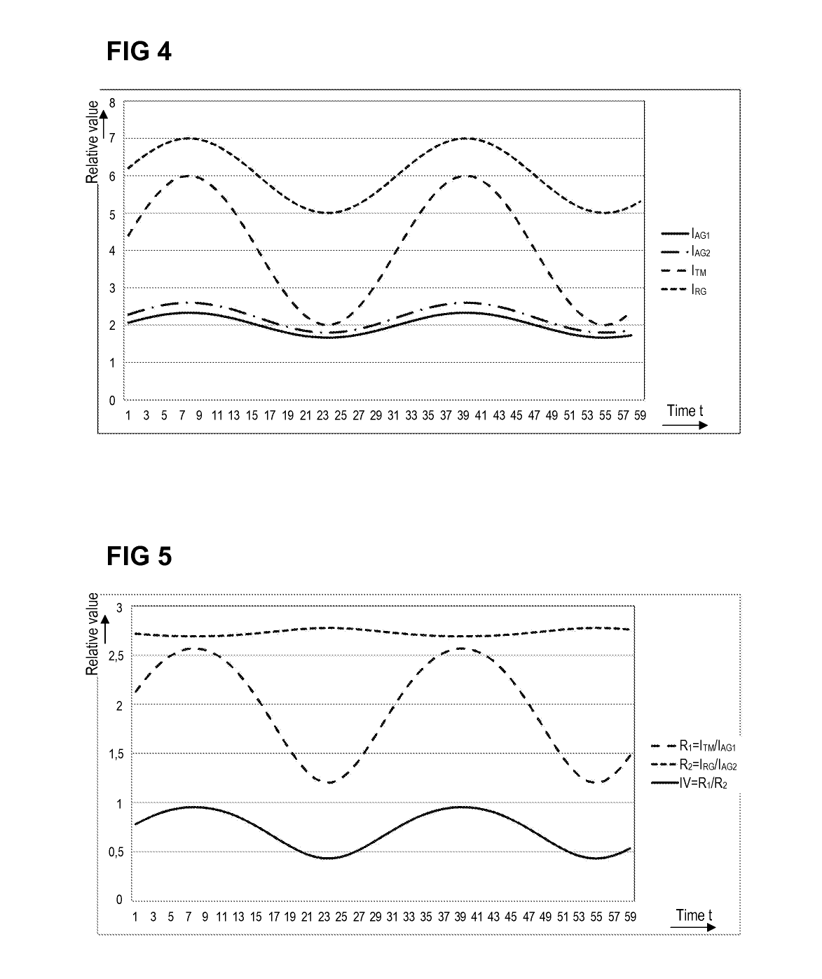

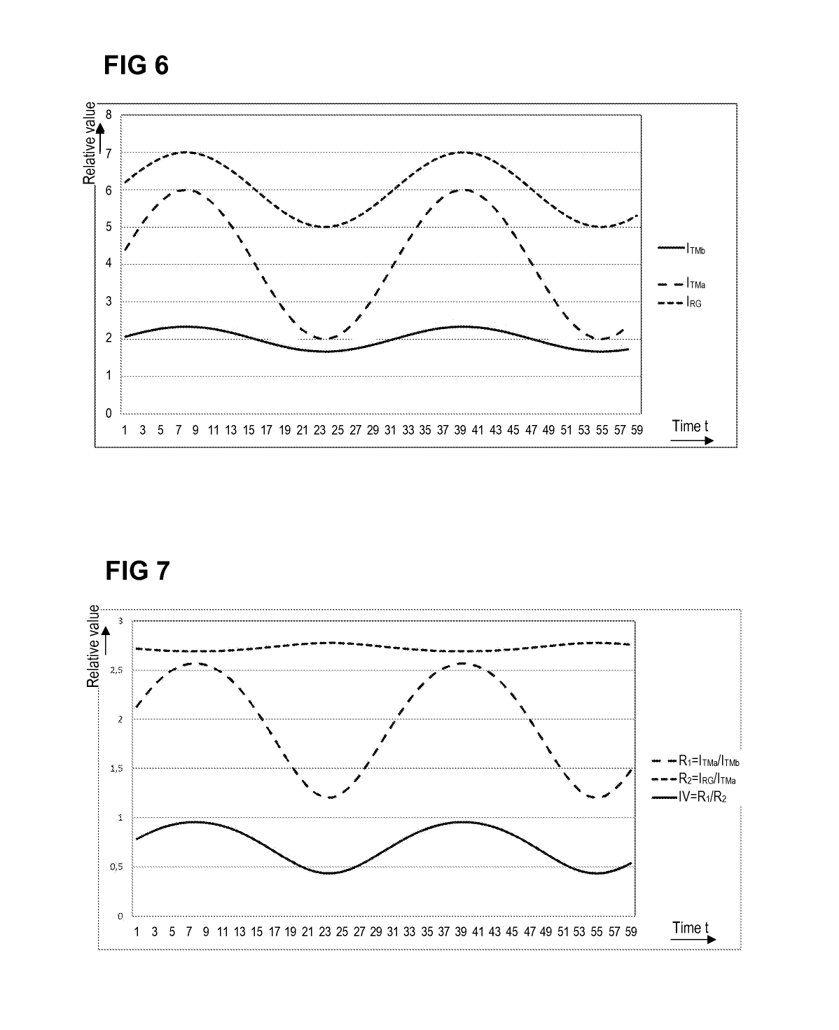

In an exemplary embodiment according to FIG. 4 and FIG. 5, a measure of the energetic excitation states of the electrons in the plasma space, and therefore a measure of the electron temperature, is determined with the aid of line intensities from multiple intensities. On the basis of this measure of the electron temperature, the single intensities are evaluated in order to derive controlled variables for setting the layer properties.

Overall, at least four intensities I₁-I₄ of the spectral lines 11 to 14 are measured as output variables and processed respectively for three of the process materials: working gas (AG), reactive gas (RG) and target material (TM). In this case, one intensity—single intensity—is respectively determined for each of two process materials (AG and TM) and at least two intensities—multiple intensity—are determined for the third process material (AG).

For the regulation, a single intensity is respectively first correlated with (mathematically related to) a multiple intensity, from which two controlled variables are obtained which, when correlated with (mathematically related to) one another, give the final controlled variable.

To first approximation, as known from the prior art, it is sufficient for the regulation when the single intensities for the process materials are taken into account. Carrying out the measurement in the vicinity of the target and the substrate further improves the regulation.

According to the invention, however, a further controlled variable is derived from two or more line intensities for the same material (multiple intensity). By forming the ratio of intensities, variations in the sensitivity of the spectrometer can be compensated for (for example also due to deposition on the collimator), as can be seen in FIG. 5, in which case the regulation according to the prior art would be insensitive.

In the example, the working gas argon is mentioned for the measurement of multiple intensities. The invention may, however, also be used for the other process materials. Likewise, the mathematical relations are indicated here only by way of example. Other mathematical relations, for example by forming differences or ratios, can also lead to practicable determination of the controlled variable.

For example, a first relative intensity R₁ is determined from an intensity of the target material I_{TM} and from a first intensity I_{AG1} of the working gas by

R₁=I_{TM}/I_{AG1}.

A second relative intensity R₂ is determined from an intensity I_{RG} of the reactive gas and from a second intensity I_{AG2} of the working gas by

R₂=I_{RG}/I_{AG2}.

The intensity relation IV, which is finally used as a controlled variable, is determined from

IV=R₁/R₂.

Improved accuracy is achieved by the concepts presented above, so that in another exemplary embodiment the doping concentration may also be determined.

With the aforementioned condition that other variables are also employed for the multiple intensity determination, for example a first relative intensity R₁ is determined from an intensity of a spectral line 14 of a first target material I_{TM a} (for example Al) and from an intensity of a spectral line 15 of a second target material I_{TM b} (for example Zn) by

R₁=I_{TM a}/I_{TM b}.

A second relative intensity R₂ is determined from an intensity I_{RG} of a spectral line 13 of the reactive gas and from the intensity I_{TM a} of the spectral line 14 of the first target material by

R₂=I_{RG}/I_{TM a}.

As an alternative, the second relative intensity R₂ may be determined from a first intensity I_{AG1} of the working gas and from a second intensity I_{AG2} of the working gas by

R₂=I_{AG1}/I_{AG2}.

The intensity relation IV, which is finally used as a measure for the doping concentration, is determined from

IV=R₁/R₂.

1. A method for determining process-specific data of a vacuum deposition process, in which a substrate is coated in a process space in a vacuum chamber by a material detached from a target connected to a magnetron while applying a target voltage provided by a regulated voltage source between the target and a back electrode and while introducing a process gas into the vacuum chamber, an optical emission spectrum being recorded and process-significant data of the vacuum deposition process being determined from intensities of spectral lines of process materials involved in coating for further processing in measurement or regulating processes, comprising the following steps:
determining at least three intensities of spectral lines of at least two process materials from the optical emission spectrum,
calculating a first relative intensity from one pair of the at least three intensities by a first mathematical relation,
calculating a second relative intensity from another pair of the at least three intensities by a second mathematical relation, and
calculating an intensity relation as a process-significant datum from the first relative intensity and the second relative intensity by a third mathematical relation, and wherein at least one of the calculating steps is performed by a processor.

2. Method according to claim 1, wherein: at least four intensities of at least two process materials are determined, the first relative intensity is calculated respectively from two of at least four the intensities which do not derive from the same process material, and the second relative intensity is calculated respectively from two others of the at least four intensities which do not derive from the same process material.

3. Method according to claim 1, wherein at least four intensities of at least two process materials are determined, the first intensity of a first spectral line of a process material and the second intensity of a second spectral line of a process material being measured at a first position in the process space and the first relative intensity being calculated from the first intensity and second intensity by the first mathematical relation,
a third intensity of the first spectral line and a fourth intensity of the second spectral line are measured at the second position in the process space different from the first position, and the second relative intensity is calculated from the third intensity and the fourth intensity by the second mathematical relation, and
the third mathematical relation is formed from the first relative intensity and the second relative intensity, and the intensity relation is used as a controlled variable in the regulating process.

4. Method according to claim 3, wherein the intensity relation is used as a controlled variable in the regulating process such that a target voltage and/or a speed of a relative movement between the magnet system and the target is tracked as a manipulated variable of the regulation so that the intensity relation as a controlled variable of the regulation is kept constant at a setpoint value of the intensity relation which is set as a reference variable.

5. Method according to claim 4, wherein the setpoint value is established from a function IV=f(a) for a value aᵢ of a layer property a to be achieved.

6. Method according to claim 5, wherein the setpoint value is determined from a function f(a) for a value aᵢ of a layer property a to be achieved, and the function is recorded during a calibration coating process by measuring values aᵢ of the layer property and, if a current value aₙ does not match the values aᵢ, modifying the target voltage and/or the speed of the relative movement between the magnet system and the target until a subsequent value aₙ₊ₓ corresponds to the value of the intended layer property a, and using the intensity relation thereby to be determined as a setpoint value and setting it as a reference variable.

7. Method according to claim 5, wherein the setpoint value is determined for a value aᵢ of a layer property a to be achieved by measuring values aᵢ of layer properties during a coating process and, if a current value aₙ does not match the values aᵢ, modifying the target voltage and/or the speed of the relative movement between the magnet system and the target until a subsequent value aₙ₊ₓ corresponds to the value of the intended layer property a, and using the intensity relation thereby to be determined as a setpoint value and setting it as a reference variable.

8. Method according to claim 3, wherein in a case of a planar magnetron, the relative movement is carried out by moving the plasma generated over the target relative to the target surface or by moving the planar magnetron relative to the substrate at a controlled speed.

9. Method according to claim 3, wherein in a case of a tubular magnetron, the relative movement is carried out by a rotational movement of a tubular target relative to the substrate and controlling rotational speed of the tubular target, a target voltage being kept constant by an oxygen flow.

10. Method according to claim 1, wherein four intensities are determined from three process materials, the first intensity being determined from a first process material, the second intensity being determined from a second process material, and the third intensity and the fourth intensity being determined from a third process material, and the first intensity is correlated with the third intensity by the first mathematical relation to form the first relative intensity, the second intensity and the fourth intensity are correlated by the second mathematical relation to form the second relative intensity, and the intensity relation is determined from the first relative intensity and the second relative intensity by the third mathematical relation and used as a controlled variable in a control loop.

11. Method according to claim 10, wherein a target voltage process parameter is used as a manipulated variable in the control loop.

12. Method according to claim 10, wherein in a case of reactive deposition processes, a reactive gas flow process parameter is used as a manipulated variable.

13. Method according to claim 12, wherein in the case of reactive deposition processes, the first to fourth intensities are determined from process materials: working gas, reactive gas and target material.

14. Method according to claim 1, wherein in a case of coating with two target materials, three intensities are determined from three process materials, the first intensity being determined from a first target material, the second intensity being determined from a second target material and the third intensity being determined from a third target material, and the first intensity is correlated with the second intensity by the first mathematical relation to form the first relative intensity, the second intensity and the third intensity are correlated by the second mathematical relation to form the second relative intensity, and the intensity relation is determined from the first relative intensity and the second relative intensity by the third mathematical relation and transmitted as a process-significant datum of a measurement for doping of a deposited layer with the one or other target material.

15. Method according to claim 14, wherein in a case of an aluminium zinc oxide (AZO) coating, the first relative intensity is determined from an intensity of a target material aluminium and from an intensity of a target material zinc, and the second relative intensity is determined from an intensity of reactive gas oxygen and the intensity of the target material aluminium or the intensity of the target material zinc.
